(19) United States
(12) Patent Application Publication
(10) Pub. No.: US 2024/0275342 A1
(43) Pub. Date: Aug. 15, 2024

(54) ENVELOPE TRACKING BIAS CIRCUIT AND ENVELOPE TRACKING BIAS METHOD THEREOF

(71) Applicant: Samsung Electro-Mechanics Co., Ltd., Suwon-si (KR)

(72) Inventors: Jongok HA, Suwon-si (KR); Jeonghoon KIM, Suwon-si (KR); Shinichi IIZUKA, Suwon-si (KR); Youngwong JANG, Suwon-si (KR); Hyejin LEE, Suwon-si (KR)

(73) Assignee: Samsung Electro-Mechanics Co., Ltd., Suwon-si (KR)

(21) Appl. No.: 18/493,045

(22) Filed: Oct. 24, 2023

(30) Foreign Application Priority Data
Feb. 14, 2023 (KR) 10-2023-0019389

(51) Int. Cl. H03F 3/24; H03F 1/02

(52) U.S. Cl. CPC H03F 3/245; H03F 1/0222; H03F 2200/102; H03F 2200/451

(57) ABSTRACT

An envelope tracking bias circuit that generates a bias current to a power amplifier that amplifies a radio frequency (RF) signal is provided. The envelope tracking bias circuit includes an envelope detector configured to detect an envelope signal of the RF signal; an envelope bandwidth detector configured to detect a frequency band of the envelope signal; and a bias output circuit that generates a bias current based on an average magnitude of the envelope signal when the frequency band of the envelope signal is greater than or equal to a predetermined frequency, and generates a bias current in response to the envelope signal when the frequency band of the envelope signal is lower than the predetermined frequency.

### CROSS-REFERENCE TO RELATED APPLICATIONS

This application claims the benefit under 35 USC § 119(a) of Korean Patent Application No. 10-2023-0019389 filed on Feb. 14, 2023, in the Korean Intellectual Property Office, the entire disclosure of which is incorporated herein by reference for all purposes.

### BACKGROUND

### 1. Field

The following description relates to an envelope tracking bias circuit and an envelope tracking bias method thereof.

### 2. Description of the Background

A method that reduces power consumption of a power amplifier that amplifies a radio frequency (RF) signal is an envelope tracking method that controls a power supply voltage level of the power amplifier according to an envelope of an RF signal.

Additionally, the envelope tracking bias technique, which controls a bias voltage or bias current provided to the power amplifier according to the envelope of the RF signal, can improve the output RF performance of the power amplifier.

The bandwidth of the RF signal in a long-term evolution (LTE) is 1.4 MHz to 100 MHZ, and high-speed operation is desired to extract the envelope of this RF signal and provide the bias voltage or the bias current according to the envelope to the power amplifier.

Additionally, the delay between the RF signal input to the power amplifier and the bias according to the envelope of the RF signal is a factor that affects the output RF performance of the power amplifier. As the frequency of the bandwidth of the RF signal increases phase shifting becomes severe and the delay increases, and thus, output RF performance may be further deteriorated.

The above information is presented as background information only to assist with an understanding of the present disclosure. No determination has been made, and no assertion is made, as to whether any of the above might be applicable as prior art with regard to the disclosure.

### SUMMARY

This Summary is provided to introduce a selection of concepts in a simplified form that are further described below in the Detailed Description. This Summary is not intended to identify key features or essential features of the claimed subject matter, nor is it intended to be used as an aid in determining the scope of the claimed subject matter.

In a general aspect, an envelope tracking bias circuit configured to output a bias current includes an envelope detector configured to detect an envelope signal of a radio frequency (RF) signal; an envelope bandwidth detector configured to detect a frequency band of the envelope signal; and a bias output circuit configured to: generate a first bias current based on an average magnitude of the envelope signal when the frequency band of the envelope signal is greater than or equal to a predetermined frequency, and generate a second bias current based on the envelope signal when the frequency band of the envelope signal is lower than the predetermined frequency.

The envelope bandwidth detector may include a limiter configured to convert the envelope signal into a pulse signal; and a counter configured to count a number of pulses of the pulse signal for a time corresponding to a pulse width of an enable counter signal, wherein a determination that a frequency band of the envelope signal is greater than or equal to the predetermined frequency is based on the number of pulses of the pulse signal.

The envelope bandwidth detector comprises an enable counter signal generator, the enable counter signal generator including an exclusive OR gate configured to generate an output signal from a trigger signal which has a predetermined pulse width and a trigger signal delayed for a predetermined time; and an AND gate configured to generate the enable counter signal from the output signal of the exclusive OR gate and the trigger signal, and output the enable counter signal to the counter.

The enable counter signal generator may further include a variable resistor and a variable capacitor configured to delay the trigger signal, and wherein the pulse width of the enable counter signal is determined based on time constants of the variable resistor and the variable capacitor.

The circuit may include an average envelope signal processor generating configured to generate a signal corresponding to the average magnitude of the envelope signal by detecting an envelope of the envelope signal; and a direct envelope signal processor configured to amplify the envelope signal and generate a signal corresponding to the envelope signal, wherein the average envelope signal processor or the direct envelope signal processor is configured to operate based on the frequency band of the envelope signal.

The bias circuit may include an envelope current generator configured to generate an envelope current corresponding to the average magnitude of the envelope signal or the envelope signal; a current source configured to supply a reference current based on the envelope current; and a bias circuit configured to generate the bias current based on the reference current.

The bias output circuit may further include a direct current generator configured to generate a direct current from a bias voltage, wherein the current source is configured to supply the reference current corresponding to a sum of the direct current and the envelope current to the bias circuit.

The envelope detector may be further configured to detect the envelope signal from the RF signal or a power supply voltage of the power amplifier that is controlled based on an envelope of the RF signal.

In a general aspect, a bias current generation method that amplifies a radio frequency (RF) signal in an envelope tracking bias circuit, includes detecting an envelope signal of the RF signal; detecting a frequency band of the envelope signal; generating a first bias current based on an average magnitude of the envelope signal when the frequency band of the envelope signal is greater than or equal to a predetermined frequency; and generating a second bias current based on the envelope signal when the frequency band of the envelope signal is lower than the predetermined frequency.

The detecting the frequency band of the envelope signal may include converting the envelope signal into a pulse signal; and determining whether a frequency band of the envelope signal is greater than or equal to the predetermined frequency based on a number of pulses of the pulse signal.

The determining whether a frequency band of the envelope signal is greater than or equal to the predetermined frequency based on a number of pulses of the pulse signal may include generating a first signal by implementing an exclusive OR operation of a trigger signal which has a predetermined pulse width and a trigger signal delayed for a predetermined time; generating an enable counter signal based on an AND operation of the first signal and the trigger signal; counting the number of pulses of the pulse signal for a time corresponding to a pulse width of the enable counter signal; and determining whether the frequency band of the envelope signal is greater than or equal to the predetermined frequency based on the number of pulses of the pulse signal.

The providing the bias current in response to the average magnitude of the envelope signal may include generating a direct current based on a bias voltage; generating a first envelope current corresponding to the average magnitude of the envelope signal; and generating the bias current based on the direct current and the first envelope current, and wherein the providing the bias current in response to the envelope signal may include generating a direct current according to a bias voltage; generating a second envelope current based on the amplified signal of the envelope signal; and generating the bias current using the direct current and the second envelope current.

The generating the first envelope current may include detecting the average magnitude of the envelope signal based on an envelope of the envelope signal.

The detecting the envelope signal may include detecting the envelope signal from the RF signal or a power supply voltage of the power amplifier controlled based on an envelope of the RF signal.

In a general aspect, a bias current generation method includes receiving, at an envelope tracking bias circuit, a radio frequency (RF) signal; detecting an envelope signal from the RF signal; determining a bandwidth frequency of the detected envelope signal; determining whether the determined bandwidth frequency is in a high frequency band or a low frequency band; generating a bias current by implementing one of a direct envelope bias mode and an average envelope bias mode based on the determined bandwidth frequency; and transmitting the generated bias current to an amplifier, wherein the average envelope bias mode is implemented based on an average magnitude of the envelope signal.

The direct envelope bias mode may be selected when the determined bandwidth frequency is in the low frequency band, and the average envelope bias mode is selected when the determined bandwidth frequency is in the high frequency band.

The bandwidth frequency may be determined based on a number of pulses of a pulse signal of the envelope signal.

Other features and examples will be apparent from the following detailed description, the drawings, and the claims.

### BRIEF DESCRIPTION OF DRAWINGS

FIG. 1 illustrates an example envelope tracking bias circuit 10, in accordance with one or more embodiments.

FIG. 2 illustrates an example of a direct envelope ENV_OUT2 and an average envelope ENV_OUT3, in accordance with one or more embodiments.

FIG. 3 illustrates a circuit diagram of the envelope detection unit 200 shown in FIG. 1.

FIG. 4 illustrates a circuit diagram of the envelope bandwidth detector 300 shown in FIG. 1.

FIG. 5 illustrates an example circuit that generates the enable counter signal EN_Count shown in FIG. 3.

FIG. 6 illustrates waveforms of signals shown in FIG. 5.

FIG. 7 illustrates a circuit diagram of the bias mode selector 400 shown in FIG. 1.

FIG. 8 illustrates a circuit diagram of the direct envelope signal processor 500 shown in FIG. 1.

FIG. 9 illustrates a circuit diagram of the average envelope signal processor 600 shown in FIG. 1.

FIG. 10 illustrates a circuit diagram of the bias output circuit 700 shown in FIG. 1.

FIG. 11 illustrates an example of the bias circuit 740 shown in FIG. 10.

FIG. 12 is a flowchart illustrating an envelope tracking bias method of the envelope tracking bias circuit 10, in accordance with one or more embodiments.

Throughout the drawings and the detailed description, unless otherwise described or provided, the same drawing reference numerals may be understood to refer to the same or like elements, features, and structures. The drawings may not be to scale, and the relative size, proportions, and depiction of elements in the drawings may be exaggerated for clarity, illustration, and convenience.

### DETAILED DESCRIPTION

The following detailed description is provided to assist the reader in gaining a comprehensive understanding of the methods, apparatuses, and/or systems described herein. However, various changes, modifications, and equivalents of the methods, apparatuses, and/or systems described herein will be apparent after an understanding of the disclosure of this application. For example, the sequences within and/or of operations described herein are merely examples, and are not limited to those set forth herein, but may be changed as will be apparent after an understanding of the disclosure of this application, except for sequences within and/or of operations necessarily occurring in a certain order. As another example, the sequences of and/or within operations may be performed in parallel, except for at least a portion of sequences of and/or within operations necessarily occurring in an order, e.g., a certain order. Also, descriptions of features that are known after an understanding of the disclosure of this application may be omitted for increased clarity and conciseness.

The features described herein may be embodied in different forms and are not to be construed as being limited to the examples described herein. Rather, the examples described herein have been provided merely to illustrate some of the many possible ways of implementing the methods, apparatuses, and/or systems described herein that will be apparent after an understanding of the disclosure of this application. The use of the term “may” herein with respect to an example or embodiment, e.g., as to what an example or embodiment may include or implement, means that at least one example or embodiment exists where such a feature is included or implemented, while all examples are not limited thereto. The use of the terms “example” or “embodiment” herein have a same meaning, e.g., the phrasing “in one example” has a same meaning as “in one embodiment”, and “one or more examples” has a same meaning as “in one or more embodiments.”

The terminology used herein is for describing various examples only and is not to be used to limit the disclosure. The articles “a,” “an,” and “the” are intended to include the plural forms as well, unless the context clearly indicates otherwise. As used herein, the term “and/or” includes any one and any combination of any two or more of the associated listed items. As non-limiting examples, terms “comprise” or “comprises,” “include” or “includes,” and “have” or “has” specify the presence of stated features, numbers, operations, members, elements, and/or combinations thereof, but do not preclude the presence or addition of one or more other features, numbers, operations, members, elements, and/or combinations thereof, or the alternate presence of an alternative stated features, numbers, operations, members, elements, and/or combinations thereof. Additionally, while one embodiment may set forth such terms “comprise” or “comprises,” “include” or “includes,” and “have” or “has” specify the presence of stated features, numbers, operations, members, elements, and/or combinations thereof, other embodiments may exist where one or more of the stated features, numbers, operations, members, elements, and/or combinations thereof are not present.

Throughout the specification, when a component or element is described as being “on”, “connected to,” “coupled to,” or “joined to” another component, element, or layer it may be directly (e.g., in contact with the other component, element, or layer) “on”, “connected to,” “coupled to,” or “joined to” the other component, element, or layer or there may reasonably be one or more other components, elements, layers intervening therebetween. When a component, element, or layer is described as being “directly on”, “directly connected to,” “directly coupled to,” or “directly joined” to another component, element, or layer there can be no other components, elements, or layers intervening therebetween. Likewise, expressions, for example, “between” and “immediately between” and “adjacent to” and “immediately adjacent to” may also be construed as described in the foregoing.

Although terms such as “first,” “second,” and “third”, or A, B, (a), (b), and the like may be used herein to describe various members, components, regions, layers, or sections, these members, components, regions, layers, or sections are not to be limited by these terms. Each of these terminologies is not used to define an essence, order, or sequence of corresponding members, components, regions, layers, or sections, for example, but used merely to distinguish the corresponding members, components, regions, layers, or sections from other members, components, regions, layers, or sections. Thus, a first member, component, region, layer, or section referred to in the examples described herein may also be referred to as a second member, component, region, layer, or section without departing from the teachings of the examples.

As used herein, the term “and/or” includes any one and any combination of any two or more of the associated listed items. The phrases “at least one of A, B, and C”, “at least one of A, B, or C”, and the like are intended to have disjunctive meanings, and these phrases “at least one of A, B, and C”, “at least one of A, B, or C”, and the like also include examples where there may be one or more of each of A, B, and/or C (e.g., any combination of one or more of each of A, B, and C), unless the corresponding description and embodiment necessitates such listings (e.g., “at least one of A, B, and C”) to be interpreted to have a conjunctive meaning.

Unless otherwise defined, all terms, including technical and scientific terms, used herein have the same meaning as commonly understood by one of ordinary skill in the art to which this disclosure pertains and specifically in the context on an understanding of the disclosure of the present application. Terms, such as those defined in commonly used dictionaries, are to be interpreted as having a meaning that is consistent with their meaning in the context of the relevant art and specifically in the context of the disclosure of the present application, and are not to be interpreted in an idealized or overly formal sense unless expressly so defined herein. The use of the term “may” herein with respect to an example or embodiment, e.g., as to what an example or embodiment may include or implement, means that at least one example or embodiment exists where such a feature is included or implemented, while all examples are not limited thereto.

Throughout the specification, the radio frequency (RF) signal may have a format according to other random wireless and wired protocols designated by, as only examples, Wi-Fi (IEEE 802.11 family, etc.), WiMAX (IEEE 802.16 family, etc.), IEEE 802.20, long term evolution (LTE), Evolution-Data Optimized (Ev-DO), high-speed packet access plus (HSPA+), high-speed downlink packet access plus (HSDPA+), high-speed uplink packet access plus (HSUPA+), Enhanced Data GSM Evolution (EDGE), Global System for Mobile communication (GSM), Global Positioning System (GPS), General Packet Radio Service (GPRS), Code Division Multiple Access (CDMA), Time Division Multiple Access (TDMA), digital enhanced cordless communication (DECT), Bluetooth, third generation (3G), fourth generation (4G), fifth generation (5G), and any other wireless and wired protocols designated thereafter, but are not limited thereto.

Additionally, unless explicitly described otherwise, the word “comprise” and variations such as “comprises” or “comprising” will be understood to imply the inclusion of stated elements but not the exclusion of any other elements.

At least one embodiment of the example embodiments provides an envelope tracking bias circuit and an envelope tracking bias method that improves RF performance degradation of a power amplifier caused by a delay between an RF signal and a bias according to an envelope of the RF signal.

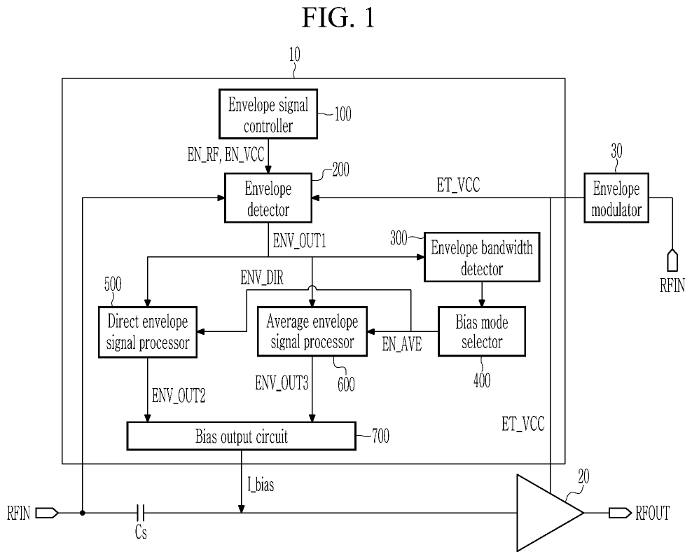

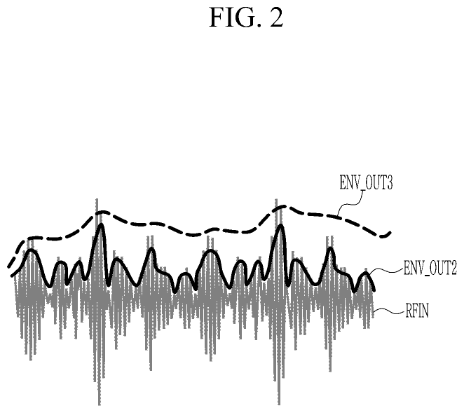

FIG. 1 is a diagram illustrating an example envelope tracking bias circuit 10, in accordance with one or more embodiments, and FIG. 2 is a diagram illustrating an example of a direct envelope ENV_OUT2 and an average envelope ENV_OUT3 according to an embodiment, in accordance with one or more embodiments.

Referring to FIG. 1, the example envelope tracking bias circuit 10 may include an envelope signal controller 100, an envelope detector 200, an envelope bandwidth detector 300, a bias mode selector 400, a direct envelope signal processor 500, an average envelope signal processor 600, and a bias output circuit 700.

The envelope signal controller 100 may transmit an envelope control signal to select one of an input radio frequency (RF) signal mode or an envelope tracking (ET) power supply voltage mode based on the characteristic parameters of the power amplifier 20 to the envelope detector 200. The envelope control signal may include an RF enable signal EN_RF indicating the input RF signal mode, and an ET power supply voltage enable signal EN_VCC indicating the ET power supply voltage mode. In the example of the input RF signal mode, the envelope signal controller 100 may enable the RF enable signal EN_RF and disable the ET power supply voltage enable signal EN_VCC. In the example of the ET power supply voltage mode, the envelope signal controller 100 may disable the RF enable signal EN_RF and enable the ET power supply voltage enable signal EN_VCC. Characteristic parameters of the power amplifier 20 may be determined according to operating characteristics of the power amplifier 20, and the operating characteristics of the power amplifier 20 may include at least one of, but not limited to, a frequency band, gain, output power, bandwidth, and power mode for a corresponding power amplifier circuit.

The envelope detector 200 receives an input RF signal RFIN and an ET power supply voltage ET_VCC output from the envelope modulator 30 to detect an envelope signal. A method of detecting an envelope signal when the power amplifier 20 operates based on ET may include an ET power supply voltage mode that uses the ET power supply voltage ET_VCC output from the envelope modulator 30 and input RF signal mode of detecting an envelope signal from an input RF signal RFIN. The envelope modulator 30 detects an envelope from the input RF signal RFIN, controls the ET power supply voltage ET_VCC according to the detected envelope, and provides the ET power supply voltage ET_VCC to the power amplifier 20. That is, since the power supply voltage of the power amplifier 20 may be controlled according to the envelope of the input RF signal RFIN, the envelope signal can be detected using the ET power supply voltage ET_VCC output from the envelope modulator 30.

The envelope detector 200 may operate in the input RF signal mode or the ET power supply voltage mode based on the RF enable signal EN_RF and the ET power voltage enable signal EN_VCC, which are envelope control signals output from the envelope signal controller 100. When the RF enable signal EN_RF is enabled, the envelope detector 200 may operate in the input RF signal mode and detect the envelope signal ENV_OUT1 from the input RF signal RFIN. When the ET power supply voltage enable signal EN_VCC is enabled, the envelope detector 200 may operate in the ET power supply voltage mode and detect the envelope signal ENV_OUT1 from the ET power supply voltage ET_VCC. The detected envelope signal ENV_OUT1 may be output to the envelope bandwidth detector 300, the direct envelope signal processor 500, and the average envelope signal processor 600.

In an example, the envelope bandwidth detector 300 may determine a bandwidth frequency (i.e., a frequency band) of the envelope signal ENV_OUT1. The envelope bandwidth detector 300 may determine whether the frequency band of the detected envelope signal ENV_OUT1 is higher than, or lower than, a predetermined frequency. In an example, the envelope bandwidth detector 300 may transfer a frequency determination signal to the bias mode selector 400.

The bias mode selector 400 may determine a bias mode based on the received frequency determination signal. The bias mode selector 400 may determine the envelope bias mode as an average envelope bias mode or a direct envelope bias mode according to the frequency discrimination signal. The bias mode selector 400 may control the direct envelope enable signal ENV_DIR or the average envelope enable signal EN_AVE based on the determined envelope bias mode.

The bias mode selector 400 may select the direct envelope bias mode when the frequency band of the envelope signal ENV_OUT1 is lower than the predetermined frequency. When the direct envelope bias mode is selected, the direct envelope enable signal ENV_DIR may be enabled and the average envelope enable signal EN_AVE may be disabled.

The bias mode selector 400 may select the average envelope bias mode when the frequency band of the envelope signal ENV_OUT1 is greater than or equal to the predetermined frequency. When the average envelope bias mode is selected, the direct envelope enable signal ENV_DIR may be disabled and the average envelope enable signal EN_AVE may be enabled.

The bias mode selector 400 may output the direct envelope enable signal ENV_DIR to the direct envelope signal processor 500 and output the average envelope enable signal EN_AVE to the average envelope signal processor 600.

The direct envelope signal processor 500 may detect the direct envelope ENV_OUT2 from the detected envelope signal ENV_OUT1. As shown in FIG. 2, the direct envelope ENV_OUT2 may have a form corresponding to the envelope signal ENV_OUT1 of the RF signal RFIN as it is, or may have a form that consistently responds according to changes in the envelope signal ENV_OUT1 of the RF signal RFIN. As an example, the direct envelope ENV_OUT2 may be generated by amplifying an envelope signal of the RF signal RFIN. The direct envelope signal processor 500 may transfer the direct envelope ENV_OUT2 to the bias output circuit 700.

The average envelope signal processor 600 may detect the average envelope ENV_OUT3 from the detected envelope signal ENV_OUT1. As shown in FIG. 2, the average envelope ENV_OUT3 may have a form corresponding to the average magnitude (amplitude) of the detected envelope signal ENV_OUT1. The average envelope signal processor 600 may transmit the average envelope ENV_OUT3 to the bias output circuit 700.

The bias output circuit 700 may generate a bias current I_bias based on the direct envelope ENV_OUT2 or the average envelope ENV_OUT3, and provide the bias current I_bias to the power amplifier 20.

When the frequency band of the envelope signal ENV_OUT1 is lower than the predetermined frequency, the delay between the RF signal RFIN and the bias according to the envelope signal ENV_OUT1 of the RF signal RFIN may not greatly affect the degradation of the RF performance of the power amplifier. Therefore, the envelope tracking bias circuit 10 operates in direct envelope bias mode providing the bias current I_bias corresponding to the direct envelope ENV_OUT2 to the power amplifier 20 when the frequency band of the envelope signal ENV_OUT1 is lower than the predetermined frequency, so that the RF performance of the power amplifier can be improved.

In an example, when the frequency band of the envelope signal ENV_OUT1 is greater than or equal to the predetermined frequency, the RF performance of the power amplifier may deteriorate due to the delay between the RF signal RFIN and the bias according to the envelope signal ENV_OUT1 of the RF signal RFIN. In this example, the envelope tracking bias circuit 10 does not operate in the direct envelope bias mode, but operates in the average envelope bias mode providing the bias current I_bias corresponding to the average envelope ENV_OUT3 to the power amplifier 20. As illustrated in FIG. 2, since the average envelope ENV_OUT3 corresponds to the average magnitude of the envelope signal ENV_OUT1, the magnitude variation may not be as great as the magnitude variation of the direct envelope ENV_OUT2. Therefore, when operating in the average envelope bias mode when the frequency band of the envelope signal ENV_OUT1 is greater than or equal to the predetermined frequency, the effect of the delay between the RF signal RFIN and the bias according to the envelope signal ENV_OUT1 of the RF signal RFIN can be reduced.

The power amplifier 20 may receive the bias current I_bias from the envelope tracking bias circuit 10, amplify the input RF signal RFIN, and output the amplified signal. At this time, the input RF signal RFIN may be input to the power amplifier 20 through the capacitor Cc.

The capacitor Cc may perform an operation of blocking a direct current (DC) component from the input RF signal RFIN.

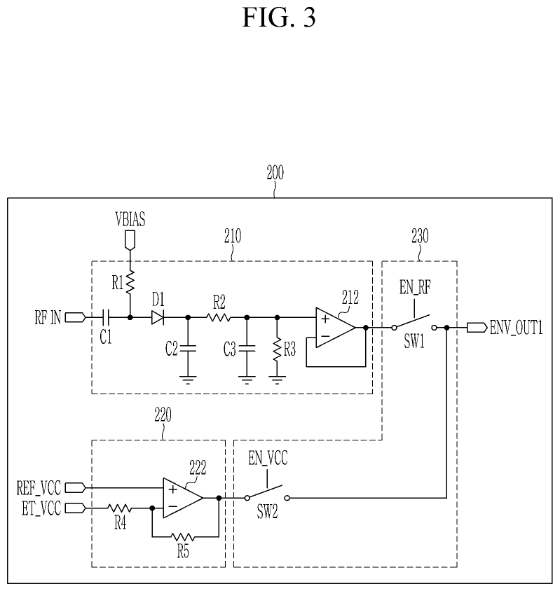

FIG. 3 is a circuit diagram of the envelope detection unit 200 shown in FIG. 1.

Referring to FIG. 3, the envelope detector 200 may output an envelope signal ENV_OUT1 using the input RF signal RFIN or the ET power supply voltage ET_VCC as an input signal. The envelope detector 200 may detect the envelope signal ENV_OUT1 from the input RF signal RFIN in response to the enabled RF enable signal EN_RF. The envelope detector 200 may detect the envelope signal ENV_OUT1 from the ET power supply voltage ET_VCC according to the enabled ET power supply voltage enable signal EN_VCC.

The envelope detector 200 may include an input RF signal mode processor 210, an ET power supply voltage mode processor 220, and a signal selector 230.

The input RF signal mode processor 210 may detect the envelope signal ENV_OUT1 from the input RF signal RFIN. The input RF signal mode processor 210 may include a capacitor C1, a resistor R1, a diode D1, a capacitor C2, a resistor R2, a capacitor C3, a resistor R3, and a buffer 212.

A cathode of the diode D1 may be connected to a first end of the capacitor C2 and a first end of the resistor R2. The second end of the capacitor C2 may be connected to ground. The second end of the resistor R2 may be connected to a first end of the capacitor C3 and a first end of the resistor R3. The second end of the capacitor C3 may be connected to ground, and the second end of the resistor R3 may also be connected to ground. The second end of the resistor R2 may be connected to an input terminal of the buffer 212. Through the diode D1 and the capacitor C3, the magnitude of the input RF signal RFIN may be detected, the magnitude of the input RF signal RFIN may be divided by the resistor R2 and the resistor R3, and the voltage divided by the resistor R2 and the resistor R3 may be input to the input terminal (+) of the buffer 212. That is, the diode D1, the capacitor C3, the resistor R2 and the resistor R3 may perform an operation of detecting the envelope signal ENV_OUT1 with respect to the input RF signal RFIN. Additionally, the buffer 212 may perform an operation of buffering the envelope signal ENV_OUT1.

The ET power supply voltage mode processor 220 may detect the envelope signal ENV_OUT1 from the ET power supply voltage ET_VCC. The ET power supply voltage mode processor 220 may include an operational amplifier 222, a resistor R4, and a resistor R5.

The resistor R4 may be connected to an inverting input terminal (−) of the operational amplifier 222, and the ET power supply voltage ET_VCC may be input to the inverting input terminal (−) of the operational amplifier 222 through the resistor R4. A reference power supply voltage REF_VCC may be input to a non-inverting input terminal (+) of the operational amplifier 222. The resistor R5 may be connected between the inverting input terminal (−) of the operational amplifier 222 and an output terminal of the operational amplifier 222. The resistor R4 and resistor R5 may determine the inverting amplification gain of the operational amplifier 222. The operational amplifier 222 inverts and amplifies the ET power supply voltage ET_VCC input to the inverting input terminal (−) with an inverting amplification gain, and may be the inverted amplified ET power supply voltage through the output terminal of the operational amplifier 222 as the envelope signal ENV_OUT1I.

The signal selector 230 may select and output one of the envelope signals ENV_OUT1 output from the input RF signal mode processor 210 or the ET power voltage mode processor 220. The signal selector 230 may include a switch SW1 and a switch SW2.

The switch SW1 may be connected to an output terminal of the input RF signal mode processor 210. The switch SW1 may be turned on or turned off based on the RF enable signal EN_RF. The switch SW1 may be turned on in response to the enabled RF enable signal EN_RF. When the switch SW1 is turned on, the envelope signal ENV_OUT1 detected from the input RF signal RFIN may be used as an output signal of the envelope detector 200.

The switch SW2 may be connected to an output terminal of the ET power voltage mode processor 220. The switch SW2 may be turned on or off according to the ET power supply voltage enable signal EN_VCC. The switch SW2 may be turned on in response to the enabled ET power supply voltage enable signal EN_VCC. When the switch SW2 is turned on, the envelope signal ENV_OUT1 detected from the ET power supply voltage ET_VCC may be used as an output signal of the envelope detector 200.

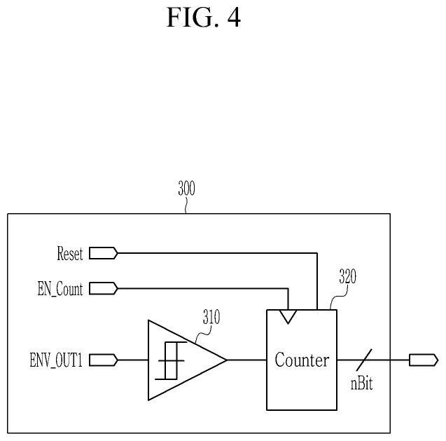

FIG. 4 is a circuit diagram of the envelope bandwidth detector 300 shown in FIG. 1.

Referring to FIG. 4, the envelope bandwidth detector 300 may include a limiter 310 and a counter 320.

The envelope signal ENV_OUT1 output from the envelope detector 200 may be input to the limiter 310.

The limiter 310 may convert the envelope signal ENV_OUT1 into a pulse signal and output the pulse signal to the counter 320.

The counter 320 operates based on an enable counter signal EN_Count, and can count the number of pulses of the input pulse signal. The enable counter signal EN_Count may be a signal having a pulse width of a specific time. The counter 320 may operate during a time corresponding to the pulse width of the enable counter signal EN_Count to count the number of pulses of the input pulse signal. The counter 320 may be reset according to a reset signal “Reset”. The number of pulses counted by the counter 320 may be output to the bias mode selector 400 in the form of the number of bits nBit. The number of pulses output in the form of the number of bits nBit may be the frequency determination signal output from the envelope bandwidth detector 300.

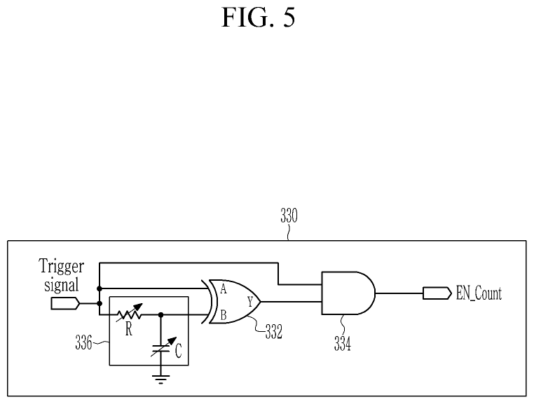

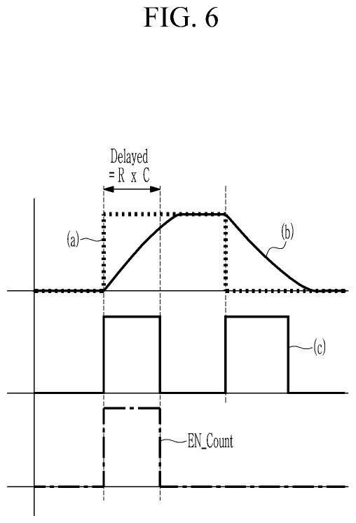

FIG. 5 is a diagram illustrating an example circuit that generates the enable counter signal EN_Count shown in FIG. 4, and FIG. 6 is a diagram showing waveforms of signals shown in FIG. 5.

Referring to FIG. 5, the enable counter signal generator 330 may generate an enable counter signal EN_Count and output the generated enable counter signal EN_Count to the counter 320. The enable counter signal generator 330 may be implemented in the envelope bandwidth detector 300.

The enable counter signal generator 330 may include an exclusive OR gate 332, an AND gate 334, and a delay circuit 336.

The exclusive OR gate 332 may have two input terminals A and B and one output terminal Y. A trigger signal having a predetermined pulse width may be directly input to the input terminal A. A trigger signal delayed by the delay processor 336 may be input to the input terminal B. The delay circuit 336 may include a variable resistor R and a variable capacitor C. The trigger signal may be input to a first end of the variable resistor R, and the second end of the variable resistor R may be connected to the input terminal B. A first end of the variable capacitor C may be connected to the input terminal B, and the second end of the capacitor C may be connected to ground. The delay time of the delay circuit 336 may be determined based on the time constant of the variable resistor R and the variable capacitor C.

The exclusive OR gate 332 generates an output signal by calculating the exclusive OR of the trigger signal having a predetermined pulse width and the trigger signal delayed by the delay circuit 336, and may output the output signal to the output terminal Y. The exclusive OR gate 332 may output ‘0’ when the two input signals are equal to each other, and output ‘1’ when the two input signals are different from each other.

The AND gate 334 may have two input terminals and one output terminal. The trigger signal may be input to one of the two input terminals of the AND gate 334, and the output signal of the exclusive OR gate 332 may be input to the other input terminal of the two input terminals of the AND gate 334. The AND gate 334 may generate an enable counter signal EN_Count by performing an AND operation of the trigger signal and the output signal of the exclusive OR gate 332 input to two input terminals, respectively. The AND gate 334 may output ‘1’ when at least one of the trigger signal and the output signal of the exclusive OR gate 332 has a value of ‘1’, and may output ‘0’ when both the trigger signal and the output signal of the exclusive OR gate 332 have a value of ‘0’.

As illustrated in FIG. 6, a trigger signal (a), which has a predetermined pulse width, is input to the input terminal A, and a trigger signal (b), which is delayed by the delay circuit 336, is input to the input terminal B. Then, an output signal (c) may be generated by the exclusive OR gate 332. Additionally, the enable counter signal EN_Count may be generated by the AND gate 334 receiving the trigger signal (a) which has a predetermined pulse width and the output signal (c) from the exclusive OR gate 332 as inputs.

That is, the pulse width of the enable counter signal EN_Count generated by the enable counter signal generator 330 may be determined by the time constant of the variable resistor R and the variable capacitor C. Accordingly, the enable counter signal generator 330 may adjust the pulse width of the enable counter signal EN_Count by adjusting the time constant of the variable resistor R and the variable capacitor C.

In an example, although FIG. 5 illustrates a method of using the time constant by the variable resistor R and the variable capacitor C to control the pulse width of the enable counter signal EN_Count, various other methods may be used. In an example, several methods may be used, such as a method of generating a pulse of a specific time period using an external oscillator or a method of generating a pulse by applying a charging current to a capacitor and comparing the charged voltage through a comparator.

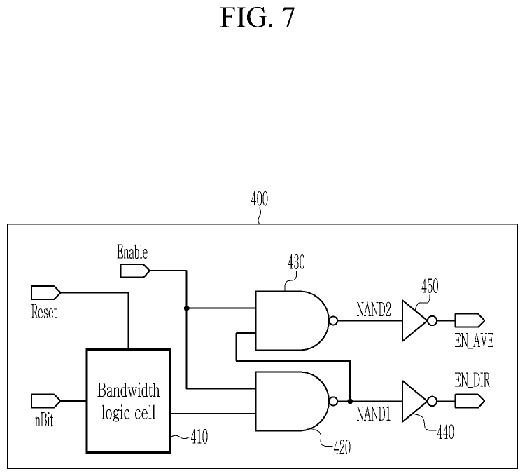

FIG. 7 illustrates a circuit diagram of the bias mode selector 400 shown in FIG. 1.

Referring to FIG. 7, the bias mode selector 400 may include a bandwidth logic cell 410, a first NAND gate 420, a second NAND gate 430, a first inverter 440, and a second inverter 450.

When the number of bits nBit representing the number of pulses counted by the counter 320 is input, the bandwidth logic cell 410 compares the number of bits with the reference number of bits. The bandwidth logic cell 410 may output a high level signal when the number of bits is less than the reference number of bits, and output a low level signal when the number of bits is greater than or equal to the reference number of bits.

The first NAND gate 420 may have two input terminals and one output terminal. One of the two input terminals of the first NAND gate 420 may be connected to the bandwidth logic cell, and an output signal of the bandwidth logic cell 410 may be input to the corresponding input terminal. An enable signal Enable may be input to the other one of the two input terminals of the first NAND gate 420. The enable signal Enable can be enabled while the power amplifier 20 is operating, and can be disabled when the power amplifier 20 is not operating. The output terminal of the first NAND gate 420 may be connected to the input terminal of the inverter 440 and one input terminal of the two input terminals of the second NAND gate 430.

The first NAND gate 420 may generate the output signal NAND1 by receiving the enable signal Enable and the output signal of the bandwidth logic cell 410. While the power amplifier 20 is operating, when the output signal of the bandwidth logic cell 410 is a high level (i.e., 1), the output signal NAND1 with a low level (i.e., 0) may be generated.

The output signal NAND1 of the first NAND gate 420 may be input to the input terminal of the first inverter 440 and one input terminal of the two input terminals of the second NAND gate 430.

The second NAND gate 430 may have two input terminals and one output terminal. The one input terminal of the two input terminals of the second NAND gate 430 may be connected to the output terminal of the first NAND gate 420, and the enable signal Enable may be input to the other input terminal of the two input terminals of the second NAND gate 430. The output terminal of the second NAND gate 430 may be connected to an input terminal of the second inverter 450.

The second NAND gate 430 may generate an output signal NAND2 by receiving the enable signal Enable and the output signal NAND1 of the first NAND gate 420. When the output signal NAND1 is at a low level (i.e., 0) while the power amplifier 20 is operating, the second NAND gate 430 may generate an output signal NAND2 with a high level (i.e., 1). The output signal NAND2 of the second NAND gate 430 may be input to an input terminal of the second inverter 450.

The first inverter 440 may invert the output signal NAND1 of the first NAND gate 420 to output the direct envelope enable signal ENV_DIR. That is, the inverted output signal NAND1 of the first NAND gate 420 may be the direct envelope enable signal ENV_DIR. When the inverted output signal NAND1 of the first NAND gate 420 has a high level (i.e., 1), it may mean that the direct envelope enable signal ENV_DIR is enabled. When the inverted output signal NAND1 of the first NAND gate 420 has a low level (i.e., 0), it may mean that the direct envelope enable signal ENV_DIR is disabled.

The second inverter 450 may invert the output signal NAND2 of the second NAND gate 430 to output the average envelope enable signal EN_AVE. That is, the inverted output signal NAND2 of the inverted NAND gate 430 may be the average envelope enable signal EN_AVE. When the inverted output signal NAND2 of the second NAND gate 430 has a high level (i.e., 1), it may mean that the average envelope enable signal EN_AVE is enabled. When the inverted output signal NAND2 of the second NAND gate 430 has a low level (i.e., 0), it may mean that the average envelope enable signal EN_AVE is disabled.

Accordingly, the bias mode selector 400 may enable the direct envelope enable signal ENV_DIR or may enable the average envelope enable signal EN_AVE according to the number of bits nBit representing the number of pulses counted by the counter 320. In addition, the bias mode selector 400 may disable the average envelope enable signal EN_AVE when the direct envelope enable signal ENV_DIR is enabled, and may disable the direct envelope enable signal ENV_DIR when the average envelope enable signal EN_AVE is enabled.

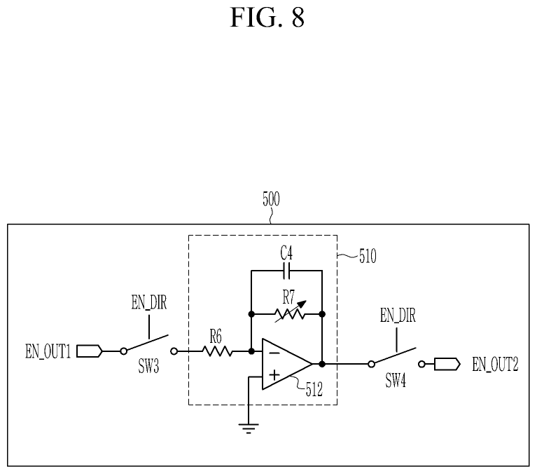

FIG. 8 illustrates a circuit diagram of the direct envelope signal processor 500 shown in FIG. 1.

Referring to FIG. 8, the direct envelope signal processor 500 may include a switch SW3, an inverting amplifier circuit 510, and a switch SW4.

The inverting amplifier circuit 510 may include a resistor R6, an operational amplifier 512, a variable resistor R7, and a capacitor C4.

The switch SW3 may be connected between an input terminal of the direct envelope signal processor 500 and a first end of the resistor R6. The second end of the resistor R6 may be connected to an inverting input terminal (−) of the operational amplifier 512. The non-inverting input terminal (+) of the operational amplifier 512 may be connected to ground. A variable resistor R7 may be connected between the output terminal of the operational amplifier 512 and the inverting input terminal (−) of the operational amplifier 512. Additionally, the capacitor C4 may be connected between the output terminal of the operational amplifier 512 and the inverting input terminal (−) of the operational amplifier 512. The inverting amplification gain of the operational amplifier 512 may be determined by the resistor R6 and the variable resistor R7.

The switch SW4 may be connected between the output terminal of the operational amplifier 512 and an output terminal of the direct envelope signal processor 500.

The switches SW3 and SW4 may be turned on or turned off in response to the direct envelope enable signal ENV_DIR. When the direct envelope enable signal ENV_DIR is enabled (i.e., high level), the switches SW3 and SW4 can be turned on. When the direct envelope enable signal ENV_DIR is disabled (i.e., low level), the switches SW3 and SW4 can be turned off. There may be only one switch among the switch SW3 and the switch SW4.

When the switches SW3 and SW4 are turned on in response to the direct envelope enable signal ENV_DIR, the envelope signal ENV_OUT1 output from the envelope detector 200 is input to the inverted input terminal (−) of the operational amplifier 512. After the envelope signal ENV_OUT1 input to the inverting input terminal (−) of the operational amplifier 512 may be inverted and amplified by the operational amplifier 512 with the inverting amplification gain, it may be output to the bias output circuit 700 through the output terminal of the operational amplifier 512.

The direct envelope signal processor 500 may generate a direct envelope ENV_OUT2 by inverting and amplifying the envelope signal ENV_OUT1 output from the envelope detector 200. At this time, if the inverting amplification gain is set small, a direct envelope ENV_OUT2 substantially identical to the envelope signal ENV_OUT1 output from the envelope detector 200 may be output. That is, the direct envelope ENV_OUT2 may have the same shape as the envelope signal ENV_OUT1 output from the envelope detector 200 and may have a different magnitude according to an inverting amplification gain.

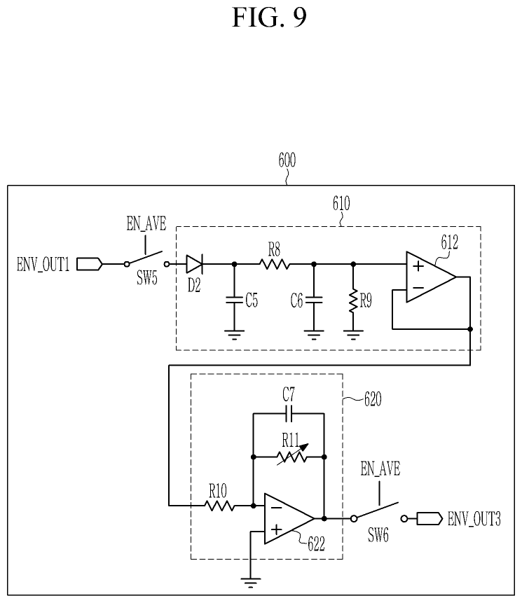

FIG. 9 illustrates a circuit diagram of the average envelope signal processor 600 shown in FIG. 1.

Referring to FIG. 9, the average envelope signal processor 600 may include a switch SW5, an envelope detector 610, an inverting amplifier circuit 620, and a switch SW6.

The envelope detector 610 may include a diode D2, a capacitor C5, a resistor R8, a capacitor C6, a resistor R9, and a buffer 612.

The switch SW5 may be connected to an input terminal of the average envelope signal processor 600 and an anode of the diode D2.

A cathode of the diode D2 may be connected to a first end of the capacitor C5 and a first end of the resistor R8. The second end of the capacitor C5 may be connected to ground. The second end of the resistor R8 may be connected to a first end of the capacitor C6 and a first end of the resistor R9. The second end of the capacitor C6 may be connected to ground, and the second end of the resistor R9 may also be connected to ground. The second end of the resistor R8 may be connected to an input terminal of the buffer 612. Through the diode D2 and the capacitor C5, the average magnitude of the envelope signal ENV_OUT1 output from the envelope detector 200 is detected, the average magnitude of the envelope signal ENV_OUT1 output from the envelope detector 200 is divided by the resistor R8 and the resistor R9, and the voltage divided by the resistor R8 and the resistor R9 may be input to the input terminal (+) of the buffer 612. That is, the diode D2, the capacitor C5, the resistor R8, the capacitor C5, and the resistor R9 may perform an operation of detecting the envelope of the envelope signal ENV_OUT1. The envelope of the envelope signal ENV_OUT1 may correspond to the average amplitude of the envelope signal ENV_OUT1. Additionally, the buffer 612 may perform an operation of buffering an envelope for the envelope signal ENV_OUT1.

The envelope for the envelope signal ENV_OUT1 may be input to the inverting amplifier circuit 620 through the buffer 612 and amplified to an appropriate magnitude through the inverting amplifier circuit 620.

The inverting amplifier circuit 620 may include a resistor R10, an operational amplifier 622, a variable resistor R11, and a capacitor C7.

A first end of the resistor R10 may be connected to the output terminal of the buffer 612, and the second end of the resistor R10 may be connected to the inverting input terminal (−) of the operational amplifier 622. The non-inverting input terminal (+) of the operational amplifier 622 may be connected to ground. The variable resistor R11 may be connected between the output terminal of the operational amplifier 622 and the inverting input terminal (−) of the operational amplifier 622. Additionally, the capacitor C7 may be connected between the output terminal of the operational amplifier 622 and the inverting input terminal (−) of the operational amplifier 622. The inverting amplification gain of the operational amplifier 622 may be determined by the resistor R10 and the variable resistor R11. The operational amplifier 622 may invert and amplify the envelope of the input envelope signal ENV_OUT1 with an inverting amplification gain, and then may output it through the output terminal of the operational amplifier 622.

The switch SW6 may be connected between the output terminal of the operational amplifier 622 and an output terminal of the average envelope signal processor 600.

The switches SW5 and SW6 may be turned on or turned off in response to the average envelope enable signal EN_AVE. When the average envelope enable signal EN_AVE is enabled (i.e., high level), the switches SW5 and SW6 can be turned on. When the average envelope enable signal EN_AVE is disabled (i.e., low level), the switches SW5 and SW6 can be turned off. In an example, there may be only one switch between the switch SW5 and the switch SW6.

When the switches SW5 and SW6 are turned on in response to the average envelope enable signal EN_AVE, the envelope for the envelope signal ENV_OUT1 detected by the envelope detector 610 may be input to the inverting input terminal (−) of the operational amplifier 622, the envelope input to the inverting input terminal (−) of the operational amplifier 622 may be inverted and amplified by the operational amplifier 622 with the inverting amplification gain, and it may be output to the bias output circuit 700 through the output terminal of the operational amplifier 622.

That is, the average envelope signal processor 600 detects an envelope (i.e., average magnitude) of the envelope signal ENV_OUT1 output from the envelope detector 200, and may generate an average envelope ENV_OUT3 by inverting and amplifying the envelope (i.e., average magnitude) of the envelope signal ENV_OUT1.

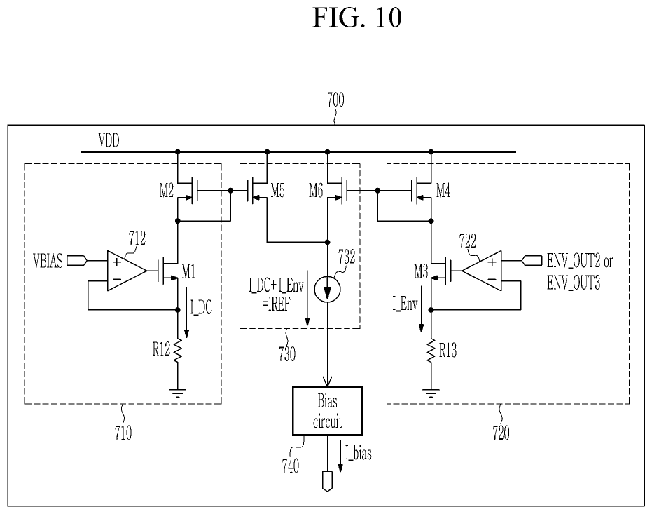

FIG. 10 is a circuit diagram of the bias output processor 700 shown in FIG. 1.

Referring to FIG. 10, the bias output circuit 700 may include a direct current generator 710, an envelope current generator 720, a reference current generator 730, and a bias circuit 740.

The direct current generator 710 may include an operational amplifier 712, a transistor M1, a transistor M2, and a resistor R12. In an example, the transistor M1 may be an N-channel transistor, and the transistor M2 may be a P-channel transistor.

The reference bias voltage VBIAS is input to the non-inverting input terminal (+) of the operational amplifier 712, and the inverting input terminal (−) of the operational amplifier 712 may be connected to a first end of the resistor R12. The second end of the resistor R12 may be connected to ground. An output terminal of the operational amplifier 712 may be connected to the gate of the transistor M1. A source of the transistor M1 may be connected to a first end of the resistor R12, and a drain of the transistor M1 may be connected to the source of the transistor M2. A drain of the transistor M2 may be connected to a power voltage terminal supplying the power voltage VDD. The direct current generator 710 may generate the direct current I_DC according to the bias voltage VBIAS.

The envelope current generator 720 may include an operational amplifier 722, a transistor M3, a transistor M4, and a resistor R13. In an example, the transistor M3 may be an N-channel transistor and the transistor M4 may be a P-channel transistor.

The direct envelope ENV_OUT2 output from the direct envelope signal processor 500 or the average envelope ENV_OUT3 output from the average envelope signal processor 600 may be input to the non-inverting input terminal (+) of the operational amplifier 722. The inverting input terminal (−) of the operational amplifier 722 may be connected to a first end of the resistor R13, and the second end of the resistor R13 may be connected to ground. An output terminal of the operational amplifier 722 may be connected to a gate of the transistor M3. A source of the transistor M3 may be connected to a first end of the resistor R13, and a drain of the transistor M3 may be connected to a source of the transistor M4. A drain of the transistor M4 may be connected to the power voltage terminal that supplies the power voltage VDD. The envelope current source circuit 720 may generate the envelope current I_Env according to the direct envelope ENV_OUT2 or the average envelope ENV_OUT3.

The reference current generator 730 may include a transistor M5, a transistor M6, and a current source 732. In an example, the transistors M5 and M6 may be P-channel transistors.

The transistor M5 may be connected to the transistor M2 of the direct current generator 710 in a form of a current mirror. A drain of the transistor M5 may be connected to the power voltage terminal supplying the power voltage VDD, and a source of the transistor M5 may be connected to a current source 732. If the size of the transistor M5 is the same as the size of the transistor M2, the direct current I_DC flowing through the transistor M2 may be mirrored and flows through the transistor M5.

The transistor M6 may be connected to the transistor M4 of the envelope current generator 720 as a form of a current mirror. A drain of the transistor M6 may be connected to the power voltage terminal supplying the power voltage VDD, and a source of the transistor M6 may be connected to the current source 732. If the size of the transistor M6 is the same as the size of the transistor M4, the envelope current I_Env flowing through the transistor M4 may be mirrored and flows through the transistor M6.

The current source 732 generates a reference current IREF from current I_DC flowing through transistor M5 and current I_Env flowing through transistor M6, and supplies the reference current IREF to the bias circuit 740. The reference current IREF supplied by the current source 732 may have the relationship of Equation 1.

$$IREF = I\_DC + I\_Env \qquad Equation 1$$

In Equation 1, the envelope current I_Env may vary according to the average envelope bias mode or the direct envelope bias mode. Assuming that the current I_DC is a constant value, the current source 732 may generate different reference currents IREF according to the bias mode.

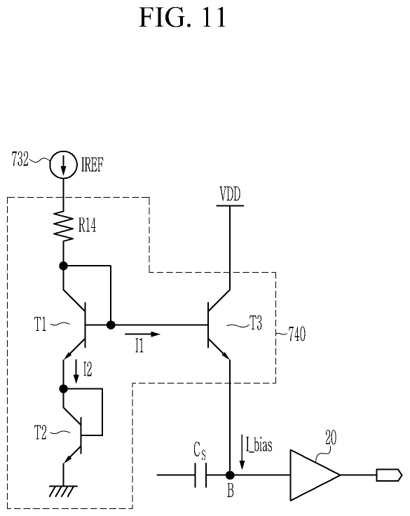

FIG. 11 is a diagram illustrating an example of the bias circuit 740 shown in FIG. 10.

Referring to FIG. 11, the bias circuit 740 may include a transistor T1, a transistor T2, a transistor T3, and a resistor R14.

The transistors T1 to T3 may be implemented with various transistors such as, but not limited to, a heterojunction bipolar transistor (HBT), a bipolar junction transistor (BJT), and an insulated gate bipolar transistor (IGBT). Additionally, although the transistors T1 to T3 are shown as n-type in FIG. 11, they may be replaced with p-type.

The base and the collector of the transistor T1 may be connected to each other, and the collector of the transistor T1 may be connected to the current source 732 through the resistor R14. The transistor T1 may have a diode connection structure. The transistor T1 may sink a current I2 from the reference current IREF.

The base and the collector of the transistor T2 may be connected to each other, and the collector of the transistor T2 may be connected to the emitter of the transistor T1. The transistor T2 may have a diode connection structure, and an emitter of the transistor T2 may be connected to ground.

A collector of transistor T3 may be connected to the power supply voltage VDD, and a base of transistor T3 may be connected to the base of transistor T2. Additionally, an emitter of the transistor T3 may be connected to an input terminal B of the power amplifier 20, and a bias current I_Bias may be supplied to the input terminal B of the power amplifier 20.

The reference current IREF may be divided into a current I1 and a current I2, and the current I1 may be input to the base of the transistor T3. Accordingly, the bias current I_bias may correspond to the current I1.

Referring to Equation 1, the reference current IREF can be calculated from the sum of the direct current I_DC and the envelope current I_Env. Assuming that the direct current I_DC is a constant value, the reference current IREF may vary according to the envelope current I_En. Assuming that the current I2 has a constant value, the current I1 may vary according to the variation of the reference current IREF.

That is, the bias circuit 740 may generate the bias current I_bias by reflecting the envelope current I_Env according to the direct envelope ENV_OUT2 or the average envelope ENV_OUT3.

FIG. 11 illustrates an example of a bias circuit 740 that provides a bias current I_bias to the power amplifier 20, and a circuit that provides a bias voltage to the power amplifier 20 may be used.

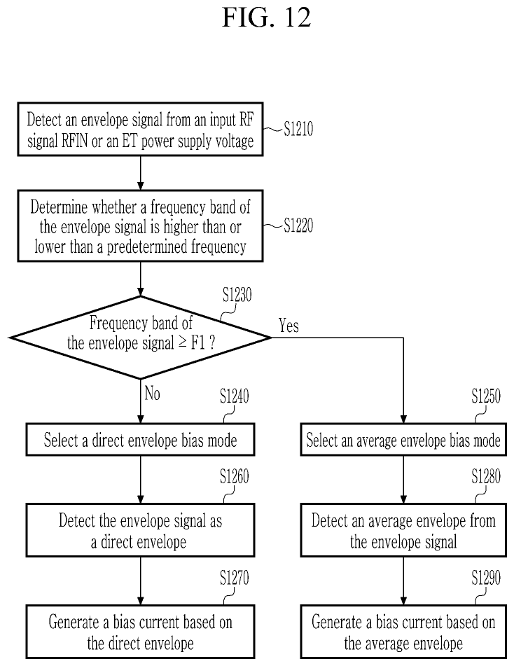

FIG. 12 is a flowchart illustrating an envelope tracking bias method of the envelope tracking bias circuit 10, in accordance with one or more embodiments.

Referring to FIG. 12, the envelope detector 200 of the envelope tracking bias circuit 10 operates in an input RF signal mode or an ET power supply voltage mode according to the envelope control signal, and may detect an envelope signal ENV_OUT1 from an input RF signal RFIN or an ET power supply voltage ET_VCC (operation S1210).

The envelope bandwidth detector 300 of the envelope tracking bias circuit 10 may determine whether a frequency band of the envelope signal ENV_OUT1 is higher than or lower than a predetermined frequency (operation S1220).

When the frequency band of the envelope signal ENV_OUT1 is lower than the predetermined frequency F1 (operation S1230), the bias mode selector 400 of the envelope tracking bias circuit 10 may select the direct envelope bias mode (operation S1240).

When the frequency band of the envelope signal ENV_OUT1 is equal to or greater than the predetermined frequency (operation S1230), the bias mode selector 400 of the envelope tracking bias circuit 10 may select the average envelope bias mode (operation S1250).

In the example of the direct envelope bias mode, the direct envelope signal processor 500 may detect the envelope signal ENV_OUT1 as the direct envelope ENV_OUT2 (S1260). The detected direct envelope ENV_OUT2 may be transmitted to the bias output circuit 700.

The bias output circuit 700 may generate a bias current I_bias based on the direct envelope ENV_OUT2 (operation S1270).

In the example of the average envelope bias mode, the average envelope signal processor 600 may detect the average envelope ENV_OUT3 by detecting the average magnitude of the envelope signal ENV_OUT1 (S1280). The detected average envelope ENV_OUT3 may be transmitted to the bias output circuit 700.

The bias output circuit 700 may generate a bias current I_bias based on the average envelope ENV_OUT3 (operation S1290).

The bias current I_bias generated by the bias output circuit 700 may be provided to the power amplifier 20.

According to at least one of the embodiments, by operating in the average envelope bias mode in a high frequency band where the RF performance of the power amplifier is severely deteriorated due to the delay between the RF signal and the bias according to the envelope of the RF signal, the RF of the power amplifier performance deterioration can be improved.

While this disclosure includes specific examples, it will be apparent to one of ordinary skill in the art, after an understanding of the disclosure of this application, that various changes in form and details may be made in these examples without departing from the spirit and scope of the claims and their equivalents. The examples described herein are to be considered in a descriptive sense only, and not for purposes of limitation. Descriptions of features or aspects in each example are to be considered as being applicable to similar features or aspects in other examples. Suitable results may be achieved if the described techniques are performed in a different order, and/or if components in a described system, architecture, device, or circuit are combined in a different manner, and/or replaced or supplemented by other components or their equivalents.

Therefore, in addition to the above disclosure, the scope of the disclosure may also be defined by the claims and their equivalents, and all variations within the scope of the claims and their equivalents are to be construed as being included in the disclosure.

What is claimed is:

1. An envelope tracking bias circuit configured to output a bias current, the circuit comprising:
an envelope detector configured to detect an envelope signal of a radio frequency (RF) signal;
an envelope bandwidth detector configured to detect a frequency band of the envelope signal; and
a bias output circuit configured to:
generate a first bias current based on an average magnitude of the envelope signal when the frequency band of the envelope signal is greater than or equal to a predetermined frequency, and
generate a second bias current based on the envelope signal when the frequency band of the envelope signal is lower than the predetermined frequency.

2. The circuit of claim 1, wherein the envelope bandwidth detector comprises:
a limiter configured to convert the envelope signal into a pulse signal; and
a counter configured to count a number of pulses of the pulse signal for a time corresponding to a pulse width of an enable counter signal,
wherein a determination that a frequency band of the envelope signal is greater than or equal to the predetermined frequency is based on the number of pulses of the pulse signal.

3. The circuit of claim 2, wherein the envelope bandwidth detector comprises an enable counter signal generator, the enable counter signal generator comprising:
an exclusive OR gate configured to generate an output signal from a trigger signal which has a predetermined pulse width and a trigger signal delayed for a predetermined time; and
an AND gate configured to generate the enable counter signal from the output signal of the exclusive OR gate and the trigger signal, and output the enable counter signal to the counter.

4. The circuit of claim 3, wherein the enable counter signal generator further comprises:
a variable resistor and a variable capacitor configured to delay the trigger signal, and
wherein the pulse width of the enable counter signal is determined based on time constants of the variable resistor and the variable capacitor.

5. The circuit of claim 1, further comprising:
an average envelope signal processor configured to generate a signal corresponding to the average magnitude of the envelope signal by detecting an envelope of the envelope signal; and
a direct envelope signal processor configured to amplify the envelope signal and generate a signal corresponding to the envelope signal,
wherein the average envelope signal processor or the direct envelope signal processor is configured to operate based on the frequency band of the envelope signal.

6. The circuit of claim 1, wherein the bias output circuit comprises:
an envelope current generator configured to generate an envelope current corresponding to the average magnitude of the envelope signal or the envelope signal;
a current source configured to supply a reference current based on the envelope current; and
a bias circuit configured to generate the bias current based on the reference current.

7. The circuit of claim 6, wherein the bias output circuit further comprises:
a direct current generator configured to generate a direct current from a bias voltage,
wherein the current source is configured to supply the reference current corresponding to a sum of the direct current and the envelope current to the bias circuit.

8. The circuit of claim 1, wherein:
the envelope detector is configured to detect the envelope signal from the RF signal or a power supply voltage of the power amplifier that is controlled based on an envelope of the RF signal.

9. A bias current generation method that amplifies a radio frequency (RF) signal in an envelope tracking bias circuit, the method comprising:
detecting an envelope signal of the RF signal;
detecting a frequency band of the envelope signal;
generating a first bias current based on an average magnitude of the envelope signal when the frequency band of the envelope signal is greater than or equal to a predetermined frequency; and
generating a second bias current based on the envelope signal when the frequency band of the envelope signal is lower than the predetermined frequency.

10. The method of claim 9, wherein the detecting the frequency band of the envelope signal comprises:
converting the envelope signal into a pulse signal; and
determining whether a frequency band of the envelope signal is greater than or equal to the predetermined frequency based on a number of pulses of the pulse signal.

11. The method of claim 10, wherein the determining comprises:
generating a first signal by implementing an exclusive OR operation of a trigger signal which has a predetermined pulse width and a trigger signal delayed for a predetermined time;
generating an enable counter signal based on an AND operation of the first signal and the trigger signal;
counting the number of pulses of the pulse signal for a time corresponding to a pulse width of the enable counter signal; and
determining whether the frequency band of the envelope signal is greater than or equal to the predetermined frequency based on the number of pulses of the pulse signal.

12. The method of claim 9, wherein the generating the bias current in response to the average magnitude of the envelope signal comprises:
generating a direct current based on a bias voltage;
generating a first envelope current corresponding to the average magnitude of the envelope signal; and
generating the bias current based on the direct current and the first envelope current, and
wherein the generating the bias current in response to the envelope signal comprises:
generating a direct current according to a bias voltage;
generating a second envelope current based on the amplified signal of the envelope signal; and
generating the bias current using the direct current and the second envelope current.

13. The method of claim 12, wherein the generating the first envelope current comprises:
detecting the average magnitude of the envelope signal based on an envelope of the envelope signal.

14. The method of claim 9, wherein the detecting the envelope signal comprises:
detecting the envelope signal from the RF signal or a power supply voltage of the power amplifier controlled based on an envelope of the RF signal.

15. A bias current generation method, comprising:
receiving, at an envelope tracking bias circuit, a radio frequency (RF) signal;
detecting an envelope signal from the RF signal;
determining a bandwidth frequency of the detected envelope signal;
determining whether the determined bandwidth frequency is in a high frequency band or a low frequency band;
generating a bias current by implementing one of a direct envelope bias mode and an average envelope bias mode based on the determined bandwidth frequency; and
transmitting the generated bias current to an amplifier,
wherein the average envelope bias mode is implemented based on an average magnitude of the envelope signal.

16. The method of claim 15, wherein the direct envelope bias mode is selected when the determined bandwidth frequency is in the low frequency band, and the average envelope bias mode is selected when the determined bandwidth frequency is in the high frequency band.

17. The method of claim 15, wherein the bandwidth frequency is determined based on a number of pulses of a pulse signal of the envelope signal.
